(19) United States
(12) Patent Application Publication
(10) Pub. No.: US 2025/0391461 A1
(43) Pub. Date: Dec. 25, 2025

(54) APPARATUS WITH SELECTION HOLD MECHANISM AND METHODS FOR OPERATING THE SAME

(71) Applicant: Micron Technology, Inc., Boise, ID (US)

(72) Inventors: Seung Yeong Seo, Frisco, TX (US); Byung S. Moon, Plano, TX (US)

(21) Appl. No.: 19/178,783

(22) Filed: Apr. 14, 2025

Related U.S. Application Data
(60) Provisional application No. 63/634,358, filed on Apr. 15, 2024.

(51) Int. Cl. G11C 11/4076

(52) U.S. Cl. CPC G11C 11/4076

(57) ABSTRACT

Methods, apparatuses, and systems related to a selection hold mechanism coupled to one or more transistors and configured to effectively replace an output from the one or more transistors. In replacing the output from the one or more transistors, the selection hold mechanism may reduce wear and degradation of the one or more transistors over time.

### CROSS-REFERENCE TO RELATED APPLICATION(S)

The present application claims priority to U.S. Provisional Patent Application No. 63/634,358, filed Apr. 15, 2024, the disclosure of which is incorporated herein by reference in its entirety.

### TECHNICAL FIELD

The disclosed embodiments relate to devices, and, in particular, to semiconductor memory devices with a selection hold mechanism and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

The configuration of the circuits can cause performance degradations over time, which can worsen the apparatus reliability, speed, and other performance metric as the apparatus gets older. For example, components in delay circuits, signal hold circuits, and the like can experience higher number of transitions or longer activation durations than other components/circuits. As a result, such components can be more susceptible to wear and degradation over time.

### BRIEF DESCRIPTION OF THE DRAWINGS

FIG. 1 is a block diagram of an apparatus in accordance with an embodiment of the present technology.

FIG. 2 is a schematic block diagram of an example delay control circuit in accordance with an embodiment of the present technology.

FIG. 3A is a schematic block diagram of a delay control circuit with an oscillator-based mitigation circuit.

FIG. 3B is a schematic block diagram of a delay control circuit with a NAND-based mitigation circuit.

FIG. 4A is a schematic block diagram of the delay control circuit with a selection hold mechanism in accordance with an embodiment of the present technology.

FIG. 4B is a timing diagram associated with the selection hold mechanism in accordance with an embodiment of the present technology.

FIG. 5 is a flow diagram illustrating an example method of operating an apparatus in accordance with an embodiment of the present technology.

FIG. 6 is a schematic view of a system that includes an apparatus in accordance with an embodiment of the present technology.

### DETAILED DESCRIPTION

As described in greater detail below, the technology disclosed herein relates to an apparatus, such as for semiconductor circuits (e.g., memory systems, systems with memory devices, related methods, etc.), for selectively replacing circuit components prone to age or use based degradation with a selection hold mechanism. The selection hold mechanism can be configured to duplicate a state or an output of the replaced circuit components for a predetermined duration.

As an illustrative example, a memory device (e.g., a dynamic random-access memory (DRAM) or a Flash/NAND memory) can include delay control circuits. In some embodiments, the delay control circuits can be used for a Row Address Strobe (RAS) chain, such as to control the timing of activation operations and precharge operations in response to receiving a Bank Activation (BankAct) signal. The delay control circuit can include two parallel paths, one for controlling the delay of the activation and another for controlling the delay of the precharge. Based on the configuration of the parallel paths (e.g., each including a sequence of CMOS or MOSFET transistors), components in the RAS chain may experience aging degradation. For example, the CMOS transistors in the parallel delay paths may provide Bias Temperature Instability (BTI) (e.g., negative BTI (NBTI)) issues associated with the increase in threshold voltage and consequent decrease in drain current and transconductance of the transistors. In using IDD values (e.g., standardized DRAM current measurements), the activation delay path can suffer from BTI degradation during IDD3N state (e.g., an active state, such as for activating a word-line without activating current flow), and the precharge delay path can suffer from the BTI degradation during IDD2N state (e.g., a quiet idle state). Over time, such degradation can lead to loss of performance in oscillating signals and response times, such as in relation to RAS-to-CAS delay (t_{RCD}) and/or precharge-recovery period (T_{RP}).

Accordingly, embodiments of the present technology use the selection hold mechanism to bypass and/or replicate outputs within the delay control circuit. For example, the selection hold mechanism can include (1) a reset circuit before one/each of the delay paths and (2) a holder circuit after the corresponding delay path and before a combining circuit that merges the output of the two paths. The reset circuit and the holder circuit can operate based on a command lock signal produced by a logic that receives an output (e.g., an internal control signal) of the combining circuit.

For the RAS chain circuit, the selection hold mechanism can allow the delay control circuit to generate an initial portion (e.g., a first predetermined number of clock cycles) of the internal control signal in response to the BankAct signal. The logic in the selection hold mechanism can receive the initial portion of the internal control signal, and in response, generate the command lock. The reset circuit can receive the command lock as a feedback and deactivate the corresponding delay path (e.g., the activation delay path for the IDD3N state and/or the precharge delay path for the IDD2N state). Simultaneously, the holder circuit can use the command lock to replicate the output of the deactivated delay path. The logic can include a timer used to remove or deactivate the command lock after a predetermine duration (e.g., a duration associated with the targeted state and the duration of the initial portion).

Accordingly, the selection hold mechanism can reduce the wear/usage of the replaced circuit and prolong the effectiveness of the replaced circuit. Moreover, even with age, the selection hold mechanism can replicate a non-degraded output of the replaced circuit for the targeted operating modes.

For brevity, the present technology is described with respect to the RAS chain. However, it is understood that various aspects of the present technology, such as the selection hold mechanism, can be implemented on other circuits, such as on other portions of the DRAM, on one or more portions of a different memory device (e.g., a NAND Flash), and/or a different type of semiconductor device (e.g., a processor).

### Example Environment

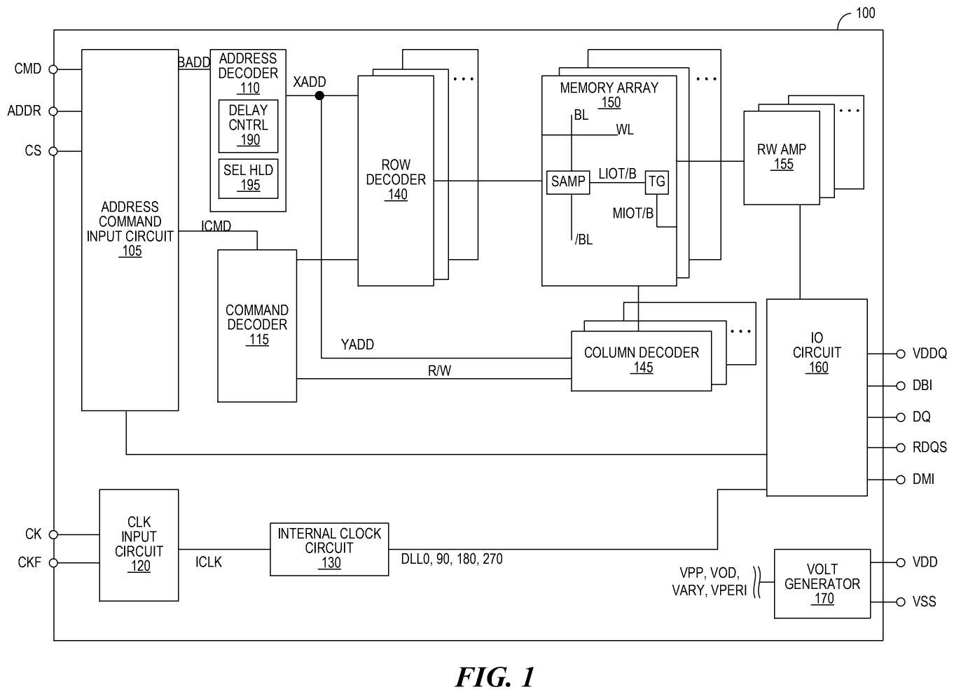

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0-15), and each bank may include a plurality of word-lines (WL), a plurality of bit lines (BL), and a plurality of memory cells arranged at intersections of the word-lines and the bit lines. Memory cells can include any one of a number of different memory media types, including capacitive, magnetoresistive, ferroelectric, phase change, or the like. The selection of a word-line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and corresponding circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, and DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials V_{DD} and V_{SS}. These power supply potentials V_{DD} and V_{SS} can be supplied to an internal voltage generator circuit 170. The internal voltage generator circuit 170 can generate various internal potentials V_{PP}, V_{OD}, V_{ARY}, V_{PERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DDQ}. The power supply potential V_{DDQ} can be supplied to the input/output circuit 160 together with the power supply potential VSS. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

The apparatus 100 can include a circuit that may be more prone to wear over time. For example, the apparatus 100 can include a delay control circuit 190 configured to control a timing for one or more targeted operations (e.g., activation and/or precharge operations in response to BankAct). To reduce such wear, the apparatus 100 can further include a selection hold mechanism 195 configured to detect targeted conditions, and in response to the detection, (1) deactivate one or more components in the delay control circuit 190 and (2) replicate an output associate with the deactivated components. Details regarding the delay control circuit 190 and the selection hold mechanism 195 are described below.

For illustrative purposes, the delay control circuit 190 and the selection hold mechanism 195 as shown as being a part of the address decoder 110. However, it is understood that the delay control circuit 190 and the selection hold mechanism 195 can be included in other circuit groupings, such as other groupings related to the RAS chain or other groupings outside of the RAS chain for other implementations.

### Adjustment Control Circuit

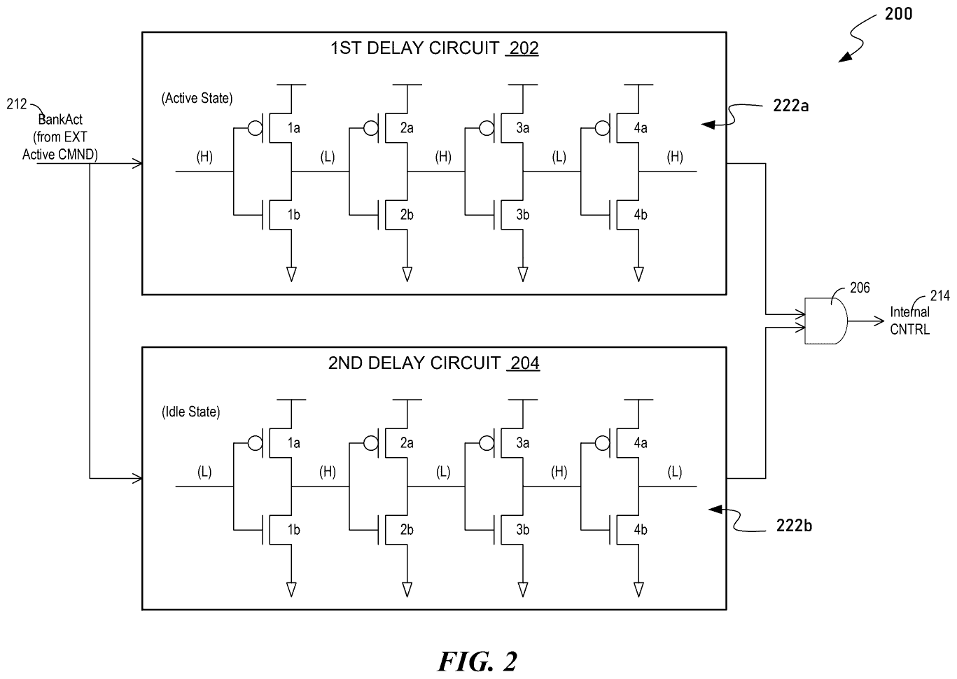

FIG. 2 is a schematic block diagram of an example delay control circuit 200 (e.g., an instance of the delay control circuit 190 of FIG. 1) in accordance with an embodiment of the present technology. The delay control circuit 200 can be configured to control timing in relating to an input signal. The delay control circuit 200 can include multiple paths, such as parallel circuit paths, used to control different timings in relation to one or more transitions in the input signal.

For the example illustrated in FIG. 2, the delay control circuit 200 can include a first delay circuit 202 connected in parallel to a second delay circuit 204. Outputs of the first delay circuit 202 and the second delay circuit 204 can be connected to a combining circuit 206 (e.g., an AND device). The first delay circuit 202 and the second delay circuit 204 can operate in reaction to an input signal 312, such as a bank activation signal (BankAct) generated in response to an external activation command. The internal outputs of the first delay circuit 202 and the second delay circuit 204 can be combined to generate an output signal 214 (e.g., an internal control signal).

The first delay circuit 202 and/or the second delay circuit 204 can include internal circuit-based configuration. In some embodiments, the first delay circuit 202 and/or the second delay circuit 204 can include a sequence of transistors. For example, the first delay circuit 202 and/or the second delay circuit 204 can (each) include a CMOS path 222 having a set of (e.g., four) CMOS devices arranged in parallel between power and ground and in series along a signal path. The first delay circuit 202 can include the CMOS path 222a, and the second delay circuit 204 can include the CMOS path 22b.

Along the signal path, each CMOS device can output a logic state that is the opposite/complement of an input logic state. For example, the CMOS path 222a can include an event number of CMOS devices that are together be configured to respond to a rising edge (e.g., a logic high, such as for an activation operation) of the input signal 212. Accordingly, the even number of CMOS can each invert the low-to-high transition, thereby replicating the low-to-high transition after a predetermined delay (e.g., according to a number and/or a size of transistors). Similarly, the CMOS path 222b can be configured to respond to a falling edge of the input signal 212, such as for an idle state or a precharge operation.

Given the configuration and the use, the first delay circuit 202 and the second delay circuit 204 (e.g., components therein) can suffer physical degradation (e.g., BTI degradation). For example, the transistors 2a and 4a in the CMOS path 222a can be subject to BTI degradation during the active state, such as the IDD3N state. Also, the transistors 2a and 4a in the CMOS path 222b can be subject to BTI degradation during the idle state, such as the IDD2N state. Over time, such BTI degradation can cause changes in the output signal 214, such as by degrading the slew rate.

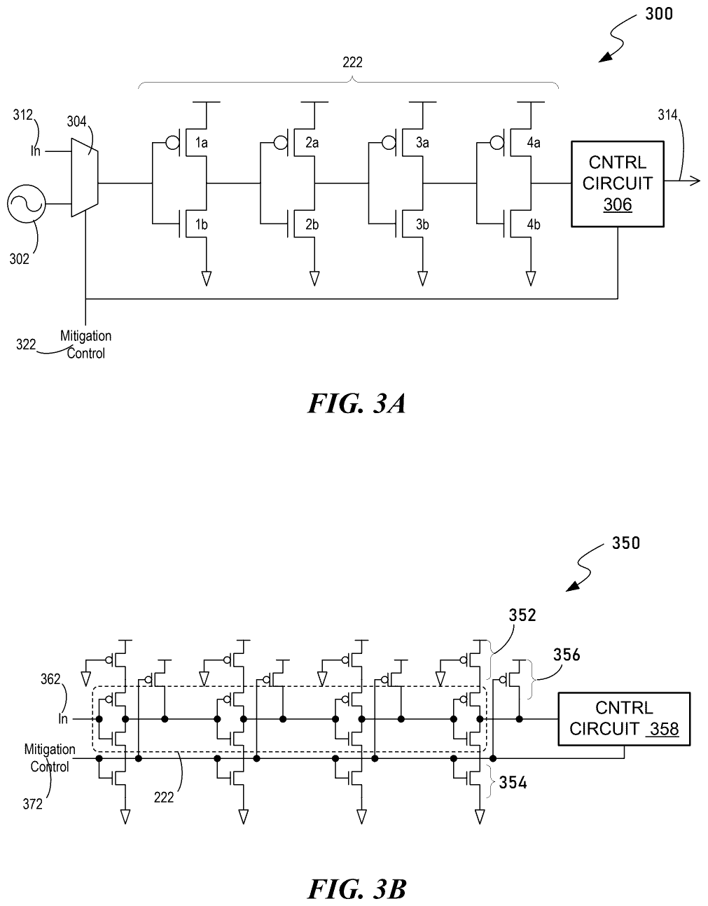

To reduce such degradation, the delay circuits (e.g., the CMOS path 222) can be coupled to mitigate circuits. For example, FIG. 3A is a schematic block diagram of a delay control circuit (e.g., the CMOS path 222) with an oscillator-based mitigation circuit 300. The oscillator-based mitigation circuit 300 can include an oscillator 302, along with an input signal 312 (e.g., matching the input signal 212 of FIG. 2), providing an input to a multiplexor 304. The output of the multiplexor 304 can be provided as an input to the CMOS path 222, and the output of the CMOS path 222 can be provided to a control circuit 306. The control circuit 306 can generate a mitigation control signal 322 along with an output signal 314 (e.g., matching the output signal 214 of FIG. 2). The mitigation control signal 322 can be fed back to the multiplexor 304 as a selection signal.

Accordingly, the oscillator-based mitigation circuit 300 can use a signal having predetermined frequency (e.g., a relatively lower frequency, such as below 100 Hz, 1 KHz, 1 MHz, etc.) from the oscillator 302 to even out the degradation of all transistors along the CMOS path 222. For example, the NBTI degradation can be applied to transistors 1a-4a during the activation period. In some embodiments, the BTI degradation at transistors 2a and 4a can be reduced by up to 50% in comparison to the CMOS path 222 without the oscillator-based mitigation circuit 300. While the oscillator-based mitigation circuit 300 can reduce the BTI degradation with the additional oscillator 302, multiplexor 304, and control circuit 306, the oscillator-based mitigation circuit 300 may allow some amount of BTI degradation to occur in the CMOS path 222.

As another example of the mitigate circuit, FIG. 3B is a schematic block diagram of a delay control circuit (e.g., the CMOS path 222) with a NAND-based mitigation circuit 350. The NAND-based mitigation circuit 350 can include a NAND type logic device coupled to each delay cell within the CMOS path 222. For example, the NAND-based mitigation circuit 350 can include, for each CMOS inverter cell within the CMOS path 222, (1) a power-input component 352 coupled between a power source (e.g., V_{dd} or drain voltage) and the CMOS inverter cell (2) a power-output component 354 coupled between the CMOS inverter cell and the Vₛₛ (e.g., source voltage or ground). The NAND-based mitigation circuit 350 can also include a post-stage component 356 connected after each CMOS inverter cell and between the power source and the signal path. The power-input component 352 can have the same bias type (e.g., PMOS) as the serially connected component in the CMOS inverter cell. Similarly, the power-output component 354 can have the same bias type (e.g., NMOS) as the serially connected component in the CMOS inverter cell and different/complementary to that of the power-input component 352. The post-stage component 356 can have the same bias type (e.g., PMOS) as the power-input component 352.

The output of the signal path can be provided to a mitigation control circuit 358. The mitigation control circuit 358 can detect the operating mode of the CMOS path 222 and generate a mitigation control signal 372 accordingly. The mitigation control signal 372 can be provided to and control operations of the post-stage component 356 and/or the power-output component 354 (e.g., via connection to the gates of such components). Thus, when the mitigation control signal 372 is activated, all nodes may be fixed to logic high, thereby preventing the PMOS components from turning on and reducing/removing the corresponding degradation. In preventing/reducing the degradation, the NAND-based mitigation circuit 350 requires increased silicon area and increased power dissipation when switching. Further, the NAND-based mitigation circuit 350 requires complex logic devices that are prone to manufacturing error.

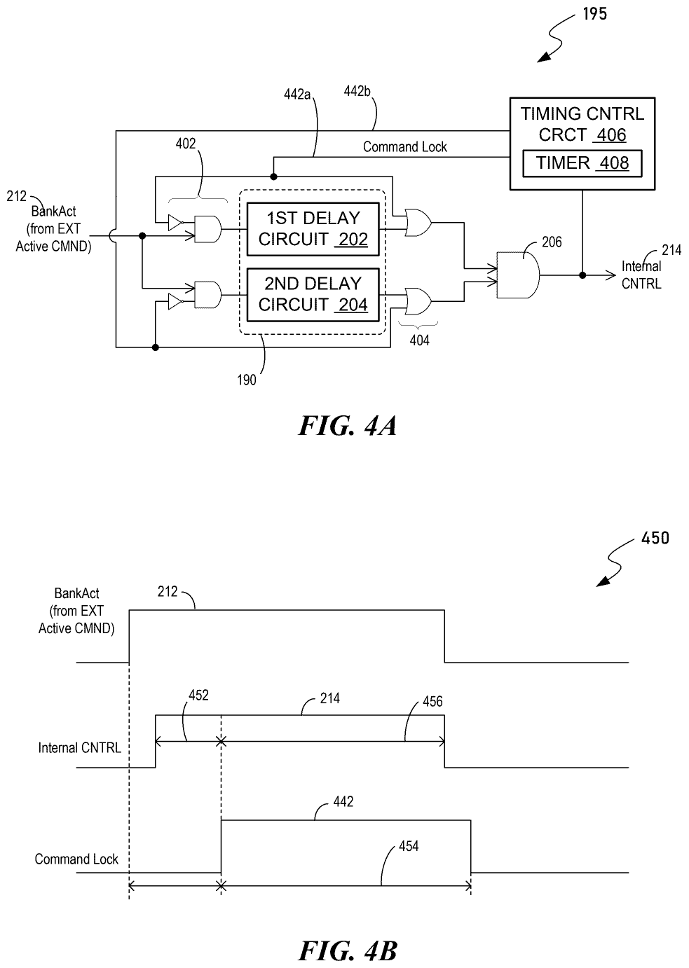

FIG. 4A is a schematic block diagram of a delay control circuit (e.g., an instance of the delay control circuit 190 of FIG. 1) with a selection hold mechanism (e.g., an instance of the selection hold mechanism 195) in accordance with an embodiment of the present technology. The delay control circuit can include the first delay circuit 202 and the second delay circuit 204 as described above. The selection hold mechanism can include a reset component 402 receiving the input signal 212 and providing its output to a corresponding one of the first delay circuit 202 and the second delay circuit 204. The selection hold mechanism can also include a holder component 404 between the combining circuit 206 and each of the first delay circuit 202 and the second delay circuit 204. Further, the selection hold mechanism can include a timing control circuit 406 that generates a command lock signal 442 based on the output signal 214 from the combining circuit 206. The command lock signal 442 can be provided to and operate the reset component 402 and the holder component 404.

The selection hold mechanism can be configured to replace the outputs of the first delay circuit 202 and the second delay circuit 204 according to the command lock signal 442. In doing so, the reset component 402 can be configured to enable/disable the operation of the corresponding one of the first delay circuit 202 and the second delay circuit 204. In some embodiments, the reset component 402 can include (1) an inverter between the command lock signal 442 and an AND device that receives an output of the inverter and the input signal 212. Accordingly, when the command lock signal 442 is inactive, the first delay circuit 202 and/or the second delay circuit 204 can operate according to the input signal 212 (e.g., BankAct).

Once the input signal 212 is initially processed through the first delay circuit 202 and/or the second delay circuit 204 (e.g., a predetermined duration or according to a signal after digit-line sensing), the corresponding output signal 214 can be provided to the timing control circuit 406, and the timing control circuit 406 can activate the command lock signal 442. The activated command lock signal 442 can cause the reset component 402 to reset or disable signal provided to the first delay circuit 202 and/or the second delay circuit 204.

Simultaneously, the activated command lock signal 442 can be provided to the holder component 404. The holder component 404 can configured to replace and maintain the output state of the first delay circuit 202 and/or the second delay circuit 204. In some embodiments, the holder component 404 can include an OR device that receives the command lock signal 442 along with an output of the corresponding one of the first delay circuit 202 and the second delay circuit 204. Accordingly, when the command lock signal 442 is inactive, the holder component 404 can allow the output of the first delay circuit 202 and/or the second delay circuit 204 to pass to the combining circuit 206. When the command lock signal 442 is active, the holder component 404 can allow the command lock signal 442 to pass to the combining circuit 206. Thus, when the command lock signal 442 is active, the holder component 404 can effectively replace the output of the disabled delay circuit with the command lock signal 442.

The timing control circuit 406 can include a timer 408 configured to track a predetermined duration that represents a remaining duration of the corresponding operation. The timing control circuit 406 can trigger the timer 408 when activating the command lock signal 442. When the timer 408 signals the end of the predetermined duration, the timing control circuit 406 can disable or deactivate the command lock signal 442.

In disabling or replacing the operation of the first delay circuit 202 and the second delay circuit 204, the selection hold mechanism can use the reset component 402 to flip the logic states on the internal nodes and prevent the delay path from being degraded by BTI. Simultaneously, the selection hold mechanism can use the holder component 404 to keep the signal into the combining circuit 206 unchanged. In contrast to the oscillator-based mitigation circuit 300 of FIG. 3 and the NAND-based mitigation circuit 350, the selection hold mechanism can prevent/reduce the BTI degradation using simpler, smaller, and less circuitry.

FIG. 4B is a timing diagram 450 associated with the selection hold mechanism in accordance with an embodiment of the present technology. The timing diagram 450 can correspond to one of the first delay circuit 202 and the second delay circuit 204. For example, the timing diagram 450 can illustrate the timing associated with the delay for the activation operation through the first delay circuit 202.

As illustrated, when the input signal 212 of BankAct transitions high, the signal can propagate through the first delay circuit 202. Such propagation can cause a relatively short delay before the output signal 214 reacts by transitioning high. The transition in the output signal 214 can be provided to the timing control circuit 406. In response, the timing control circuit 406 can transition the command lock signal 442 after a delay cycle 452 (e.g., a predetermined duration representative of an event, such as the digit-line sensing). The command lock signal 422 can be sustained for a hold duration 454 predetermined for the timer 408. As such, the selection hold mechanism can replace the operation of the delay path at least for a replaced duration 456 or the hold duration 454, thereby removing the BTI effect on the delay path for the corresponding duration of time.

### Control Flow

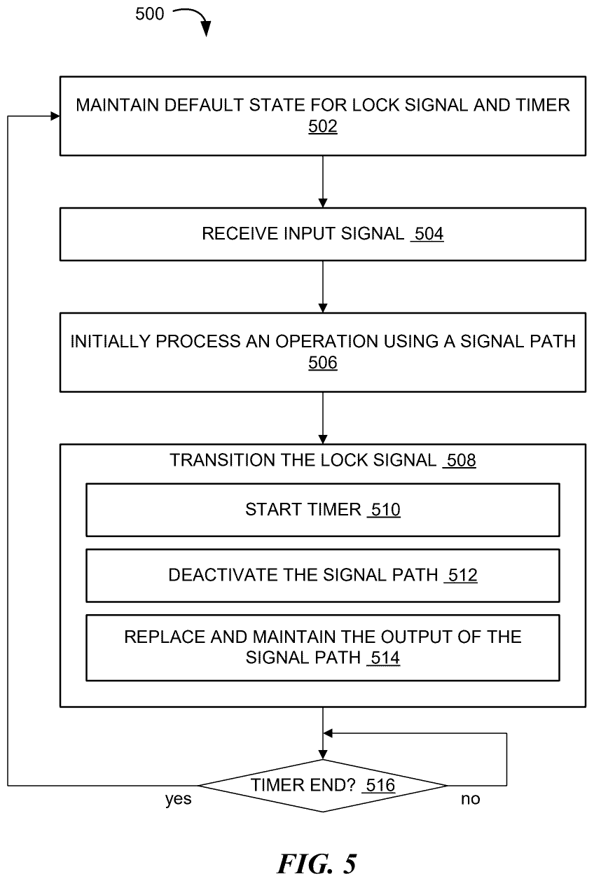

FIG. 5 is a flow diagram illustrating an example method 500 of operating an apparatus (e.g., the apparatus 100 of FIG. 1) in accordance with an embodiment of the present technology. The method 500 can be for operating the delay control circuit 190 of FIG. 1 and FIG. 4A, the selection hold mechanism 195 of FIG. 1 and FIG. 4A, or a combination thereof. The method 500 can be for operating the selection hold mechanism 195 to replace outputs of the delay control circuit 190, such as the CMOS path 222 of FIG. 2 therein, thereby reducing preventing BTI degradation of the components (e.g., MOSFET devices) within the delay control circuit 190.

At block 502, the selection hold mechanism 195 can maintain a default state for a lock signal outside of the targeted operations, such as the activation operation and/or the precharge operation. For example, the selection hold mechanism 195 can use the timing control circuit 406 of FIG. 4A to maintain a default state (e.g., inactive state) for the command lock signal 442 of FIG. 4A. Also, the selection hold mechanism 195 can maintain the timer 408 at a default state (e.g., reset/stopped state), such as by resetting the timer after a predetermined duration (e.g., the hold duration 454 of FIG. 4B).

At block 504, the delay control circuit 190 and the selection hold mechanism 195 can receive an input signal. For example, the selection hold mechanism 195 (e.g., at the reset components 402 of FIG. 4A, such as the AND device therein) can receive the input signal 212, such as the BankAct signal. In receiving the input signal 212, the selection hold mechanism 195 can detect or respond to a targeted transition (e.g., a rising edge) of the input signal 212.

At block 506, in response to the received input signal, the delay control circuit 190 and the selection hold mechanism 195 can initially process an operation using a signal path, such as a sequence of transistors (e.g., the CMOS path 222 or other MOSFET circuits). For example, the selection hold mechanism 195 can allow the received input signal to propagate through to the delay control circuit 190, and the delay control circuit 190 can allow the input signal to propagate through the signal path to generate an output signal, such as the path output and/or the corresponding output signal 214 of FIG. 2. As a more specific example, the selection hold mechanism 195 can generate a logic high output in response to the rising edge of the BankAct signal, thereby causing the first delay circuit 202 of FIG. 4A and/or the second delay circuit 204 of FIG. 4A can output a logic high path output.

At block 508, the selection hold mechanism 195 can control or transition the lock signal in response to the output from the initial processing. As described above, the timing control circuit 406 can receive or detect the transition in the input signal 212 or a processing result thereof. In response, the timing control circuit 406 can control or activate the command lock signal 442. In some embodiments, the timing control circuit 406 can activate the command lock signal 442 after a predetermined delay, such as the delay cycle 452 of FIG. 4B that corresponds to an operational event (e.g., bit-line sensing) or a number of clock cycles required for a signal to traverse through the signal path and other targeted components. At block 510, the timing control circuit 406 can activate the timer 408 simultaneously as controlling or transitioning the lock signal.

Transitioning the lock signal can correspond to deactivating the signal path as illustrated in block 512. As described above, the reset component 402 (e.g., the inverter and the AND device) can respond to the activated command lock signal 442 and invert the input into the first delay circuit 202 and/or the second delay circuit 204. In other words, the reset component 402 can invert the input (e.g., different from the input signal 212) into the first delay circuit 202 and/or the second delay circuit 204. Effectively, the reset component 402 can deactivate the communication path in response to the activated command lock signal 442.

Transitioning the lock signal can also correspond to replacing and maintaining the output of the signal path as illustrated in block 514. As described above, the holder component 404 can respond to the activated command lock signal 442 by allowing such command lock signal 442 to pass through downstream. Effectively, the holder component 404 can provide the command lock signal 442 (e.g., a logic hi at this point) instead or in place of an output from (e.g., a logic low given the inverted input into) the delay path. Thus, the selection hold mechanism 195 can simultaneously (1) use the reset component 402 to deactivate the signal path or put the signal path in a state less susceptible to BTI degradation while (2) using the holder component 404 to maintain a previous output state (e.g., before deactivating) of the signal path after deactivation of the signal path.

At decision block 516, the selection hold mechanism 195 (e.g., the timing control circuit 406) can determine whether the timer 408 has reached a predetermined duration (e.g., the hold duration 454). Until the predetermined duration is reached, the selection hold mechanism 195 can maintain the activated state of the command lock signal 442. Once the timer reaches the end, the selection hold mechanism 195 can return the command lock signal 442 to the default state (e.g., deactivated or low state) and reset the timer 408 as illustrated by a feedback loop to block 502. The predetermined duration can extend at least up to an end of the targeted operation and/or a corresponding duration for the received input signal. Accordingly, when the command lock signal 442 is returned to the default state, the signal path can remain deactivated and the replicated/reproduced output (e.g., the activated command lock signal 442 through the holder component 404) can also be returned to a default state.

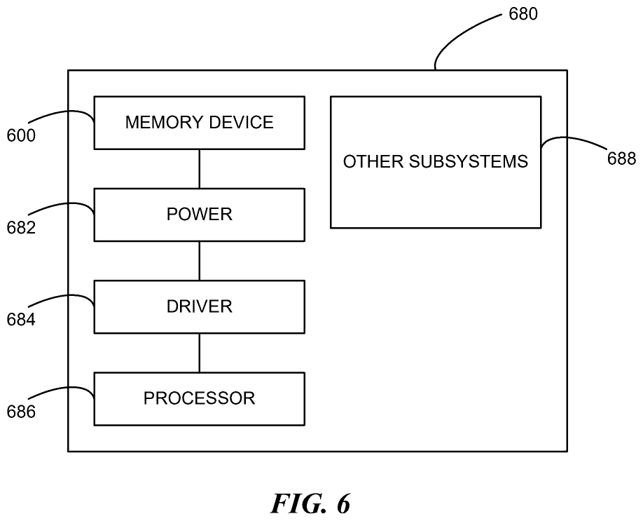

FIG. 6 is a schematic view of a system that includes an apparatus in accordance with embodiments of the present technology. Any one of the foregoing apparatuses (e.g., memory devices) described above with reference to FIGS. 1-3 can be incorporated into any of a myriad of larger and/or more complex systems, a representative example of which is system 680 shown schematically in FIG. 6. The system 680 can include a memory device 600, a power source 682, a driver 684, a processor 686, and/or other subsystems or components 688. The memory device 600 can include features generally similar to those of the apparatus described above with reference to FIGS. 1-5, and can therefore include various features for performing a direct read request from a host device. The resulting system 680 can perform any of a wide variety of functions, such as memory storage, data processing, and/or other suitable functions. Accordingly, representative systems 680 can include, without limitation, hand-held devices (e.g., mobile phones, tablets, digital readers, and digital audio players), computers, vehicles, appliances and other products. Components of the system 680 may be housed in a single unit or distributed over multiple, interconnected units (e.g., through a communications network). The components of the system 680 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-6.

I/we claim:

1. A memory device, comprising:
a delay control circuit configured to implement one or more internal delays associated with one or more memory operations, wherein the delay control circuit includes at least one delay path; and
a selection hold mechanism coupled to the delay control circuit and configured to selectively deactivate the delay path and maintain a path output of the deactivated delay path for reducing exposure of the delay path to Bias Temperature Instability (BTI) degradation, the selection hold mechanism including:
a reset component before the delay path and configured to (1) receive and initially provide an input signal to the delay path and (2) negate the input signal into the delay path according to a command lock signal;
a holder component after the delay path and configured to (1) initially provide the path output downstream and (2) replace the path output with the command lock signal when the command lock signal is activated; and
a timing control circuit configured to control the command lock signal in response to an output of the holder component, wherein the timing control circuit is configured activate the command lock signal in response to the initially provided portion of the path output for negating the input signal into the delay path and replacing the path output with the command lock signal.

2. The memory device of claim 1, wherein the delay control circuit is configured to implement the one or more internal delays for a row address strobe (RAS) signal.

3. The memory device of claim 2, wherein:
the at least one delay path includes (1) a first delay circuit and (2) a second delay circuit;
the reset component is a first reset component before the first delay circuit;
the holder component is a first holder component after the first delay circuit;
the selection hold mechanism includes:
a second reset component before the second delay circuit;
a second holder component after the second delay circuit; and
the memory device further comprising:
a combining circuit receiving outputs from the first and second holder components and generating an internal control signal, wherein the internal control signal is provided as an input to the timing control circuit for controlling the command lock signal.

4. The memory device of claim 3, wherein:
the first delay circuit is configured to implement one or more delays associated with an activation operation; and
the second delay circuit is configured to implement one or more delays associated with a precharging operation.

5. The memory device of claim 4, wherein the timing control circuit is configured to activate the command lock signal after a delay cycle from the input signal, wherein the delay cycle corresponds to a digit-line sensing event.

6. The memory device of claim 5, wherein the timing control circuit is configured to deactivate the command lock signal to a default state after a hold duration that corresponds to the delay cycle along with the activation operation, the precharging operation, or a combination thereof.

7. The memory device of claim 1, wherein the holder component includes an OR device receiving the command lock signal and the output of the delay path.

8. The memory device of claim 1, wherein the reset component includes (1) an inverter receiving the command lock signal and (2) an AND device receiving an output of the inverter and the input signal, wherein an output of the AND device is provided to the delay path.

9. The memory device of claim 1, wherein the delay path includes a sequential set of CMOS inverters configured to delay the input signal.

10. The memory device of claim 1, wherein the memory device comprises a Dynamic Random-Access Memory (DRAM) device.

11. A method of operating an apparatus, the method comprising:
receiving an input signal;
initially communicating the input signal through a delay path to generate an output signal;
activating a command lock signal based on the output signal;
based on activating the command lock signal:
inverting an input into the delay path for reducing exposure of the delay path to Bias Temperature Instability (BTI) degradation; and
providing the command lock signal as the output signal in place of an output from the delay path.

12. The method of claim 11, wherein the command lock signal is activated after a delay cycle from the input signal, the delay cycle corresponding to a digit-line sensing event.

13. The method of claim 11, further comprising:
reverting the activated command lock signal to a default non-activated state after a predetermined duration.

14. The method of claim 13, wherein:
the apparatus is a memory device;
the delay path comprises a circuitry for row address strobe (RAS); and
the predetermined duration corresponds to an activation operation, a precharge operation, or both.

15. The method of claim 14, wherein the input signal is a memory bank activation (BankAct) signal.

16. An apparatus, comprising:
one or more MOSFETs configured to provide an output in response to an input;
a selection hold mechanism coupled to the one or more MOSFETs and configured to selectively change a state of the one or more MOSFETs while maintaining the output for reducing exposure of the one or more MOSFETs to Bias Temperature Instability (BTI) degradation, the selection hold mechanism including:
a reset component before the one or more MOSFETs and configured to (1) receive and initially provide the input to the delay path and (2) negate the input into the one or more MOSFETs according to a command lock signal;
a holder component after the one or more MOSFETs and configured to (1) initially provide the output from the one or more MOSFETs downstream and (2) provide the command lock signal as the output when the input is negated for the one or more MOSFETs; and
a timing control circuit configured to control the command lock signal in response to the output, wherein the timing control circuit is configured activate the command lock signal in response to an initial portion of the output.

17. The apparatus of claim 16, wherein the apparatus comprises a memory device.

18. The apparatus of claim 17, wherein the one or more MOSFETs comprise a delay circuit associated with a memory operation.

19. The apparatus of claim 18, wherein the one or more MOSFETs comprise a set of CMOS devices configured to provide a delay for an activation operation, a precharging operation, or both.

20. The apparatus of claim 18, wherein:
the one or more MOSFETs is configured to process a row address strobe (RAS) signal; and
the input signal is a memory bank activation (BankAct) signal.
